(19) United States
(12) Patent Application Publication
(10) Pub. No.: US 2026/0132333 A1
(43) Pub. Date: May 14, 2026

(54) CONVERSION SUBSTANCE, MIXTURE OF SUBSTANCES, PROCESS FOR THE PRODUCTION OF A CONVERSION SUBSTANCE AND RADIATION-EMITTING COMPONENT

(71) Applicant: ams-OSRAM International GmbH, Regensburg (DE)

(72) Inventors: Mark VORSTHOVE, Augsburg (DE); Barbara HUCKENBECK, Denklingen (DE); Frank JERMANN, Koenigsbrunn (DE)

(21) Appl. No.: 19/118,360

(22) PCT Filed: Oct. 4, 2023
(86) PCT No.: PCT/EP2023/077436

§ 371 Date: Apr. 4, 2025

(30) Foreign Application Priority Data
Oct. 12, 2022 (DE) 10 2022 126 560.9

(51) Int. Cl. C09K 11/77; C01G 15/00; H10H 29/851

(52) U.S. Cl. CPC C09K 11/7774; C01G 15/006; C09K 11/7769; H10H 29/8512; C01P 2002/50; C01P 2002/76; C01P 2006/60

(57) ABSTRACT

A conversion substance of the general formula RE¹₃₋ₓRE²ₓ(Sc_{5-y-z}Al_{y}Ga_{z})O₁₂ is provided, wherein RE¹ is an element or a combination of elements selected from the group of rare earth elements, RE² is an element or a combination of elements selected from the group of rare earth elements, RE¹ and RE² are selected differently from each other, and it is 0<x≤3, 0≤y≤5, 0<z≤5 and y+z≤5. A mixture of substances, a process for the production of a conversion substance and a radiation-emitting component are further disclosed.

A conversion substance, a mixture of substances, a process for the production of a conversion substance and a radiation-emitting component are disclosed.

The task of at least one embodiment is to provide a conversion substance with improved properties. The task of at least one further embodiment is to provide a mixture of substances with improved properties. The task of at least one further embodiment is to provide a process for the production of a conversion substance with improved properties. The task of at least one further embodiment is to provide a radiation-emitting component with improved properties. These tasks are solved by a conversion substance, a mixture of substances, a process and a radiation-emitting component according to the independent claims.

A conversion substance is provided. According to at least one embodiment, the conversion substance comprises the general formula RE¹₃₋ₓRE²ₓ(Sc_{5-y-z}Al_{y}Ga_{z})O₁₂. There, RE¹ is an element or a combination of elements selected from the group of rare earth elements, RE² is an element or a combination of elements selected from the group of rare earth elements, RE¹ and RE² are selected differently from each other, and it is 0<x≤3, 0≤y≤5, 0<z≤5 and y+z≤5. In particular, x can be selected from the range 0.25<x<0.65.

The term “conversion substance” is used here and in the following to refer to a material that is designed to absorb electromagnetic radiation. The absorbed radiation leads completely or partially to a charge transport within the conversion substance and finally to a defect at which a radiation-free recombination of the charges occurs. If this process only takes place partially, the conversion substance also has wavelength-converting properties. Part of the absorbed radiation is thereby converted to electromagnetic radiation that has a different wavelength maximum than the electromagnetic radiation absorbed by the conversion substance. For example, the conversion substance absorbs radiation with a wavelength maximum at shorter wavelengths than the emission maximum and thus emits radiation with an emission maximum shifted towards red.

According to one embodiment, RE² is an activator element. In particular, the conversion substance may comprise a crystalline, for example ceramic, host material into which RE² is incorporated as an activator element. The conversion substance is, for example, a ceramic material.

An activator element changes the electronic structure of the host material in such a way that electromagnetic radiation of a first wavelength range can be absorbed by the conversion substance. This so-called primary radiation can excite an electronic transition in the conversion substance, which leads to radiation-free recombination. Optionally, the excited state also returns to the ground state by partially emitting electromagnetic radiation of a second wavelength range, also known as secondary radiation. The activator element, which is introduced into the host material, is thus responsible—if present—for the wavelength-converting properties of the conversion substance.

Conversion substances are described here and below using molecular formulas. The elements listed in the molecular formulae are present in charged form. Here and in the following, elements and/or atoms in relation to the molecular formulas of the conversion substances therefore refer to ions in the form of cations and anions, even if this is not explicitly stated. This also applies to element symbols if these are given without a charge number for the sake of clarity.

It is possible with the given molecular formulas that the conversion substance comprises further elements, for example in the form of contaminations. Taken together, these contaminations have a maximum of 5 mol %, in particular a maximum of 1 mol %, preferably a maximum of 0.1 mol %.

Rare earth elements include here the chemical elements of the 3rd subgroup of the periodic table as well as the lanthanides. Rare earth elements are generally selected from the group formed by scandium, yttrium, lanthanum, cerium, praseodymium, neodymium, promethium, samarium, europium, gadolinium, terbium, dysprosium, holmium, erbium, thulium, ytterbium and lutetium.

In so-called modular system platforms for LEDs (light-emitting diodes), individual components are interchangeable. The aim is to provide a modular system in which as many different LED derivatives as possible can be used, comprising different colors, white color locations and, in particular, brightnesses. Up to now, different brightnesses have mainly been implemented using different chip sizes and chip types (chip sourcing) in order to cover a brightness range of 20 mcd to 4 cd, for example. The specific designs of the chips and possibly low individual volumes of individual derivatives mean that a complex chip portfolio must be kept available in order to be able to provide the modular system platforms over a long period of time, for example for longer than 10 years, which is particularly relevant in the automotive sector. The properties of the LED must not change over this period, especially not the visual impression. This causes undesirable additional costs.

Until now, it has not been possible to generate different LED brightnesses with one type of chip without changing either the operating current or the chip in terms of its shape or function. Such a change is achieved, for example, by dimming using oversized bond pads. This approach results in high production costs, as the LED designs required for different brightnesses are only needed in small quantities and the individual LED chips are therefore very expensive in their manufacture. In combination with the running time and continuous generations of the products, chip sourcing is therefore extremely complex, time-consuming and expensive.

One way to simplify the complex chip sourcing and thus reduce costs would be the use of carbon black as a broadband absorber to reduce the efficiency of the component. However, this would lead to a change in the visual appearance of the component, which is normally not desirable.

Furthermore, it is possible in principle to introduce an additional conversion substance into the LED that has a reduced quantum efficiency. However, it has been shown that the use of interfering elements such as Sm³⁺, which is usually used for this purpose, can significantly reduce the quantum efficiency, but leads to additional emissions that undesirably change the emission color of the component. In addition, it is very difficult to reproducibly guarantee an exact reduction in the quantum efficiency of a light-emitting substance using interfering elements. Otherwise, no alternatives are known to date that specifically absorb the emission of an LED chip, for example a blue emission, without changing the other properties of the component.

The conversion substance described here enables the use of only one or only a few different chip types and sizes to realize a broad brightness portfolio without changing in particular the optical impression of a component containing the conversion substance.

The conversion substance described here is based on a garnet structure of known light-emitting substances, such as the cerium-doped garnet phosphor Y₃Al₅O₁₂:Ce (YAG:Ce), which has a yellow body color. Such light-emitting substances, possibly together with other light-emitting substances, can absorb the emission of blue-emitting LED chips and convert it into green-yellow secondary radiation. Previously known garnet light-emitting substances have a high absorption in the emission range of blue-emitting chips and a high quantum efficiency. By adapting the structure (e.g. partial replacement of individual elements), it is possible to vary the position of both the excitation band and the emission band. So far, garnet systems have been optimized for high conversion efficiency.

In order to reduce the quantum efficiency, the conversion substance described here absorbs the primary radiation, for example blue light from an LED, but does not convert it at least partially into visible light. Without or with reduced quantum efficiency of the conversion substance described herein and simultaneously high absorption of the primary radiation, the brightness of the overall emission can be reduced. In particular, if the conversion substance is used together with a garnet light-emitting substance such as YAG:Ce, the color location, for example a white color location, of a component is not negatively affected, so that a broad brightness portfolio can be provided with one chip type and one light-emitting substance by adding only one further material, the conversion substance.

In order to achieve the reduced quantum efficiency, in the conversion substance described here the incorporation of interfering elements, which usually lead to undesirable side effects such as additional absorption in the visible spectral range, can be omitted. Instead, concentration quenching takes place in the conversion substance described here, which leads to a reduction in the quantum efficiency. Depending on the desired reduced quantum efficiency, the proportion of RE², which acts as an activator in the conversion substance, can be selected within the general formula to be so high that, after excitation, there is no longer an emission of electromagnetic radiation, but a charge transport from one activator ion to the next and ultimately to a defect at which radiation-free recombination occurs.

In the crystal lattice of the known garnet light-emitting substance YAG:Ce, the larger Ce³⁺ ion with a diameter of 1.14 pm only fits to a small proportion, for example to a proportion of 3%, on the dodecahedron sites of the Y³⁺ ion with a diameter of 1.02 pm. In contrast, the conversion substance described here has an expanded crystal lattice, which makes it possible to increase the proportion of activator ions. The expansion is achieved by the at least partial or even complete replacement of Al³⁺ by larger ions, namely the replacement of Al³⁺ on the octahedron sites by Sc³⁺ and the replacement of Al³⁺ on the tetrahedron sites by Ga³⁺. Furthermore, Y³⁺ on the dodecahedron sites can be at least partially replaced by an RE¹, in particular an RE¹ with a larger diameter, for example by Gd³⁺. The expansion of the crystal lattice allows up to 15%, in particular up to 30%, up to a maximum of 100% of RE¹ to be replaced by the activator RE². This high proportion of activator ions RE² leads to a strong emission quenching and at the same time to a high absorption of the conversion substance. By adjusting the content of RE², it is possible to adjust the strength and width of the absorption band, as well as the level of quantum efficiency.

Furthermore, the desired position of the absorption band and—if present—the emission band of the conversion substance can be set by varying the aluminum content and/or by adjusting the ratio of the proportions of Sc, Ga and RE¹ to each other. On the one hand, this enables the conversion substance to be adapted to a light-emitting substance if this is used together with the conversion substance in a component. In particular when using garnet light-emitting substances, the conversion substance described here can be adapted to the light-emitting substance in such a way that it is optically indistinguishable from the light-emitting substance and also has similar or identical absorption and emission locations. On the other hand, if the conversion substance has an emission, it can also be used alone as a light-emitting substance in which the desired brightness can be set via the RE² content.

With the conversion substance described here, alone or in combination with a light-emitting substance, a broad brightness portfolio can be provided using only one or a few chip types, thus drastically reducing the need for costly chip sourcing.

According to at least one embodiment, RE¹ is an element or a combination of elements selected from the group Gd, Y, La and Lu. In particular, RE¹ is Gd or a combination of Gd and Y, for example RE¹ is Gd. Thus, the smaller Y³⁺ is partially or completely replaced by the larger Gd³⁺, which contributes to the expansion of the crystal lattice described above.

According to at least one embodiment, RE² is an element or a combination of elements selected from the group Ce and Eu. In particular, RE² is Ce. Ce and Eu are typical activator elements.

According to at least one embodiment, the conversion substance has the general formula Gd₃₋ₓCeₓ(Sc_{5-y-z}Al_{y}Ga_{z})O₁₂. In this, RE² is the activator element Ce and RE¹ is Gd. Depending on the selected x, up to 100% of Gd can be replaced by Ce, whereby a high activator concentration and thus a high concentration quenching can be achieved. Such a conversion substance can thus be well tuned to the desired quantum efficiency to adjust the brightness of the overall emission.

According to at least one embodiment, the conversion substance has an absorption range with an absorption maximum in the UV to blue spectral range. Thus, the conversion substance can have an essentially identical absorption behavior as a light-emitting substance, in particular a garnet phosphor, for example YAG:Ce. When such a light-emitting substance is combined with the conversion substance, the color location, for example the white color location of an LED, is thus not or only slightly influenced.

According to at least one embodiment, the absorption maximum is in the range from including 430 nm up to and including 490 nm.

According to at least one embodiment, the conversion substance has a quantum efficiency selected from the range ≥0% to <100%. This means that the quantum efficiency of the conversion substance can be adjusted depending on the desired brightness. The setting can be made either via the conversion substance alone or as a mixture with a suitable light-emitting substance. The optical impression of a component containing the conversion substance and a light-emitting substance, in particular a garnet phosphor, is not or hardly negatively influenced, as would be the case, for example, if it were used with carbon black. This simple way of adjusting the brightness reduces the otherwise high complexity of chip sourcing, for example in modular platforms.

According to at least one embodiment, the quantum efficiency is <20%, in particular <15%. Furthermore, with the conversion substance described here, a quantum efficiency of <1%, for example 0.5%, can be realized with a suitable composition. At the same time, despite reduced brightness, the remission of the conversion substance in the primary radiation range, for example in the emission range of a blue emitting chip, can be below 10%, i.e. the conversion substance can have a high absorption in the relevant range.

According to at least one embodiment, the light-emitting substance comprises a crystalline, for example ceramic, host lattice. The light-emitting substance is, for example, a ceramic material.

According to at least one embodiment, the conversion substance crystallizes in a cubic space structure. In particular, the conversion substance crystallizes in the space group Ia3d. Thus, the conversion substance crystallizes in the same space structure as the garnet-based light-emitting substances, for example YAG:Ce.

In particular, the crystalline host lattice is made up of a three-dimensional unit cell that generally repeats periodically. In other words, the unit cell is the smallest recurring unit of the crystalline host lattice. The elements RE¹, RE², Sc, Al, Ga and O each occupy fixed positions, so-called point positions, of the three-dimensional unit cell of the host lattice.

Six lattice parameters are required to describe the three-dimensional unit cell of the crystalline host lattice, three lengths a, b and c and three angles α, β and γ. The three lattice parameters a, b and c are the lengths of the lattice vectors that span the unit cell. The other three lattice parameters α, β and γ are the angles between these lattice vectors. α is the angle between b and c, β is the angle between a and c, and γ is the angle between a and b. In the case of a cubic spatial structure, the lengths are the same and it is therefore sufficient to specify the length a. Furthermore, the angles are each 90°.

According to at least one embodiment, the conversion substance has a lattice parameter a which is selected from the range >12.20 Å. This means that the crystal lattice of the conversion substance is enlarged or widened compared to a crystal lattice of YAG-based garnet light-emitting substances. YAG-based garnet light-emitting substances generally have lattice parameters a of <12.20 Å, for example about 12.016 Å. The expanded crystal lattice allows a high concentration of RE², which in turn is responsible for the reduced quantum efficiency.

A mixture of substances is also specified. The conversion substance described herein is suitable and adapted to be used in a mixture of substances described herein. All features disclosed with respect to the conversion substance thus also apply to the mixture of substances and vice versa.

According to at least one embodiment, the mixture of substances comprises a conversion substance as described above and a light-emitting substance, wherein the light-emitting substance has the general formula RE¹₃₋ₖRE²ₖ(Al,Ga)₅O₁₂, wherein RE¹ is an element or a combination of elements selected from the group of rare earth elements, RE² is an element or a combination of elements selected from the group of rare earth elements, RE¹ and RE² are selected differently from each other, and 0<k≤0.2 applies.

The term “light-emitting substance” is understood here and in the following to mean a wavelength conversion substance, i.e. a material that is set up to absorb and emit electromagnetic radiation. In particular, the light-emitting substance absorbs electromagnetic radiation that has a different wavelength maximum than the electromagnetic radiation emitted by the light-emitting substance. For example, the light-emitting substance absorbs radiation with a wavelength maximum at shorter wavelengths than the emission maximum and thus emits radiation with an emission maximum shifted towards red. Pure scattering or pure absorption are not understood as wavelength-converting in the present case.

The light-emitting substance may comprise the elements RE¹ and RE² as defined above in relation to the conversion substance. The light-emitting substance is a garnet phosphor. In contrast to the conversion substance, however, the light-emitting substance has no or only a less expanded crystal lattice, since Al³⁺ is only partially substituted by Ga³⁺, if at all, for example with a proportion of at most 40%. Accordingly, the content of RE², which acts as an activator element, is lower compared to the conversion substance. A reduction in quantum efficiency due to concentration quenching therefore does not take place in the light-emitting substance.

The mixture of substances thus combines a garnet-based light-emitting substance and the garnet-based conversion substance described here. While the light-emitting substance is optimized for high quantum efficiency, the conversion substance has an adjustable reduced quantum efficiency. By adding only one further material, namely the conversion substance described here, the overall brightness of the radiation emitted by the mixture of substances upon excitation can thus be adjusted as desired without the optical impression being negatively influenced by the conversion substance.

According to at least one embodiment, the conversion substance is present in the mixture of substances in a proportion ranging from >0% to <100%.

According to at least one embodiment, the light-emitting substance has an absorption range with an absorption maximum, wherein the absorption maximum has a position which is essentially identical to a position of the absorption maximum of the conversion substance.

“Essentially identical” here and in the following means that two quantities to be compared are exactly identical, differ only within the scope of measurement inaccuracies or differ only to such an extent that they are not perceptible to an external observer.

Due to the essentially identical position of the absorption maxima, there is a high overall absorption, while the conversion substance has at least partially no emission. This means that the brightness of the mixture of substances can be reduced compared to the brightness of the pure light-emitting substance.

According to at least one embodiment, the light-emitting substance and the conversion substance have emission spectra that are essentially identical. This means that the total emission of the mixture of substances is changed little or not at all compared to the emission of the pure light-emitting substance, which means that the color location of the total emission is not negatively affected and remains essentially unchanged while the brightness is reduced.

According to at least one embodiment, the mixture of substances comprises the conversion substance of the general formula Gd₃₋ₓCeₓ(Sc_{5-y-z}Al_{y}Ga_{z})O₁₂. According to at least one further embodiment, the mixture of substances comprises the light-emitting substance YAG:Ce.

A process for the production of a conversion substance is further disclosed. The process is suitable for producing a conversion substance as described herein. All features disclosed in connection with the conversion substance and the mixture of substances thus also apply to the process and vice versa.

According to at least one embodiment, the process is used to prepare a conversion substance of the general formula RE¹₃₋ₓRE²ₓ(Sc_{5-y-z}Al_{y}Ga_{z})O₁₂, wherein RE¹ is an element or a combination of elements selected from the group of rare earth elements, RE² is an element or a combination of elements selected from the group of rare earth elements RE¹ and RE² are selected differently from each other, and it is 0<x≤3, 0≤y≤5, 0<z≤5 and y+z≤5.

Furthermore, the process has the following steps:
Providing a mixture of reactants selected from a group comprising oxides, nitrides, carbonates, nitrates, oxalates, citrates and hydroxides of each of RE¹, RE², Sc, Al and Ga and combinations thereof,
homogeneous mixing of the reactants,
heating the reactants to a temperature selected from the range including 1200° C. to including 1900° C.

This process can be used to easily produce the conversion substance in which the desired brightness, absorption and, if necessary, emission can be set.

The conversion substance is formed during the heating.

For example, Gd₂O₃, CeO₂, Al₂O₃, Sc₂O₃ and Ga₂O₃ can be selected as reactants to produce a conversion substance of the general formula Gd₃₋ₓCeₓ(Sc_{5-y-z}Al_{y}Ga_{z})O₁₂. For example, 1500° C. can be selected as the temperature.

Optionally, one or more fluxing agents can be added to the mixture of reactants. This allows the grain size and morphology of the conversion substance and the synthesis process to be improved. In particular, round grains with low dispersion, for example, can be produced in a targeted manner.

According to at least one embodiment, Al and/or Ga are present in excess in the mixture of reactants. This makes it possible to avoid the formation of undesirable secondary phases such as YAlO₃ or Y₄Al₂O₉ during the production of the conversion substance.

According to at least one embodiment, the heating is carried out in a forming gas atmosphere. According to at least one embodiment, the heating is carried out for a period of 1 h to 5 h, for example for 3 h. The heating can further be carried out in a vessel, for example an Al₂O₃ crucible. In particular, the vessel can be closed with a lid during heating.

After heating, the conversion substance obtained can be crushed and ground, for example using a mortar grinder.

A radiation-emitting component is further disclosed. The radiation-emitting component is arranged and intended to contain a conversion substance described herein or a mixture of substances described herein. All the features disclosed in connection with the conversion substance and the mixture of substances and the process for the production of the conversion substance thus also apply to the radiation-emitting component and vice versa.

According to at least one embodiment, the radiation-emitting component has a semiconductor chip which, during operation, emits electromagnetic radiation of a first wavelength range, and a conversion element which has a conversion substance with the above-mentioned features or a mixture of substances with the above-mentioned features, and which converts electromagnetic radiation of the first wavelength range into electromagnetic radiation of a second wavelength range which is partially different from the first wavelength range.

The electromagnetic radiation of the first wavelength range forms the emission spectrum of the semiconductor chip and is also referred to as primary radiation.

The semiconductor chip is, for example, a light-emitting diode chip or a laser diode chip. The component can thus be a light-emitting diode (LED) or a laser. Preferably, the semiconductor chip has an epitaxially grown semiconductor layer sequence with an active zone that is suitable for generating electromagnetic radiation. For example, the active zone has a pn junction, a double heterostructure, a single quantum well or a multiple quantum well structure.

During operation, the semiconductor chip can emit electromagnetic radiation, for example from the ultraviolet spectral range and/or from the visible spectral range, in particular from the blue spectral range. The primary radiation thus has wavelengths from the range 300 nm to 500 nm, in particular 430 nm to 490 nm, for example.

The conversion element is arranged in particular on the radiation exit surface of the semiconductor chip and is located, for example, in the beam path of the semiconductor chip, so that at least some of the radiation emitted by the semiconductor chip strikes the conversion element.

The conversion substance or the mixture of substances in the conversion element partially convert electromagnetic radiation of the first wavelength range into electromagnetic radiation of a second wavelength range. The electromagnetic radiation of the second wavelength range forms the emission spectrum of the conversion substance or mixture of substances and is also referred to as secondary radiation.

The electromagnetic radiation of the second wavelength range is at least partially different from the first wavelength range. The light-emitting substance in the mixture of substances or the conversion substance itself, which are contained in the conversion element, give the conversion element wavelength-converting properties. For example, the conversion element only partially converts the electromagnetic radiation of the semiconductor chip into electromagnetic radiation of the second wavelength range, while another part of the electromagnetic radiation of the semiconductor chip is transmitted by the conversion element.

In this case, the radiation-emitting component emits mixed light, which is composed of electromagnetic radiation of the first wavelength range and electromagnetic radiation of the second wavelength range. The mixed light includes, for example, white light. If the primary radiation is completely converted by the conversion element and/or there is no transmission of primary radiation by the conversion element, this is referred to as full conversion. In this case, the radiation-emitting component emits the secondary radiation emitted by the conversion element.

Depending on the proportion of the conversion substance in the substance mixture or depending on the proportion of RE² in the conversion substance, the brightness of the secondary radiation is reduced compared to secondary radiation generated by a pure light-emitting substance. The component can therefore emit with a brightness that is adapted to the respective requirements. The shape and size of the semiconductor chip does not have to be changed for this. The brightness can be adjusted solely by the composition of the conversion substance and/or the proportion of conversion substance in the mixture of substances.

If only the conversion substance is used in the conversion element, its absorption band and emission band can be adapted by varying the aluminum content. In the mixture of substances, the conversion substance can be adapted to the absorption and emission band of the light-emitting substance in such a way that both the color location of the overall emission is essentially retained and no graying occurs due to additional absorption bands of the conversion substance in the emission range of the light-emitting substance.

The conversion substance or mixture of substances can be embedded in a matrix material. The conversion substance or the mixture of substances is then present in particle form. According to one embodiment, the matrix material is selected from a group comprising polymers and glass. The polymers that can be selected include, for example, polystyrene, polysiloxane, polysilazane, PMMA, polycarbonate, polyacrylate, polytetrafluoroethylene, polyvinyl, silicone resin, silicone, epoxy resin and transparent synthetic rubber. Silicates, water glass and quartz glass, for example, can be selected as glass.

According to at least one embodiment, the conversion element is designed as a conversion layer. The conversion layer can be applied in direct or indirect contact with the semiconductor chip. In the case of indirect contact, it can be applied to the semiconductor chip, in particular to its radiation exit surface, by means of an adhesive layer, for example, or there can be a potting between the semiconductor chip and the conversion element.

According to a further embodiment, the semiconductor chip, optionally the conversion element and, if applicable, adhesive layer can also all be surrounded by a potting. For example, the semiconductor chip, the conversion element and, optionally, an adhesive layer are then arranged in the recess of a housing in which the potting is also arranged.

A potting can have a transmittance for primary radiation and/or secondary radiation of at least 85%, preferably 95%. Furthermore, potting can be made of silicone or epoxy resin, for example.

Further advantageous embodiments and further embodiments of the light-emitting substance, the component and the process result from the exemplary embodiments described below in conjunction with the figures.

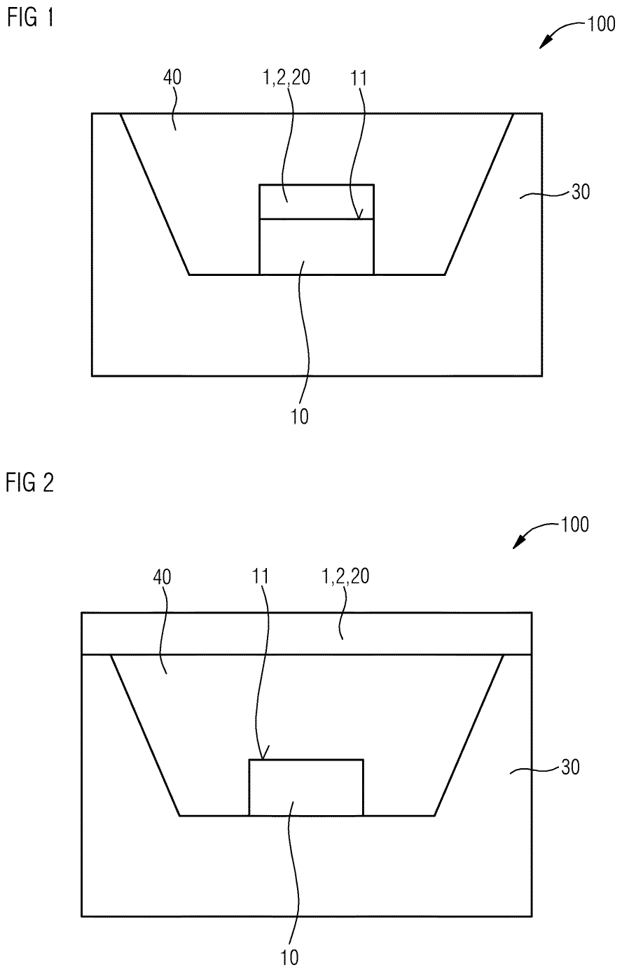

FIGS. 1 and 2 each show a schematic sectional view of a radiation-emitting component according to exemplary embodiments.

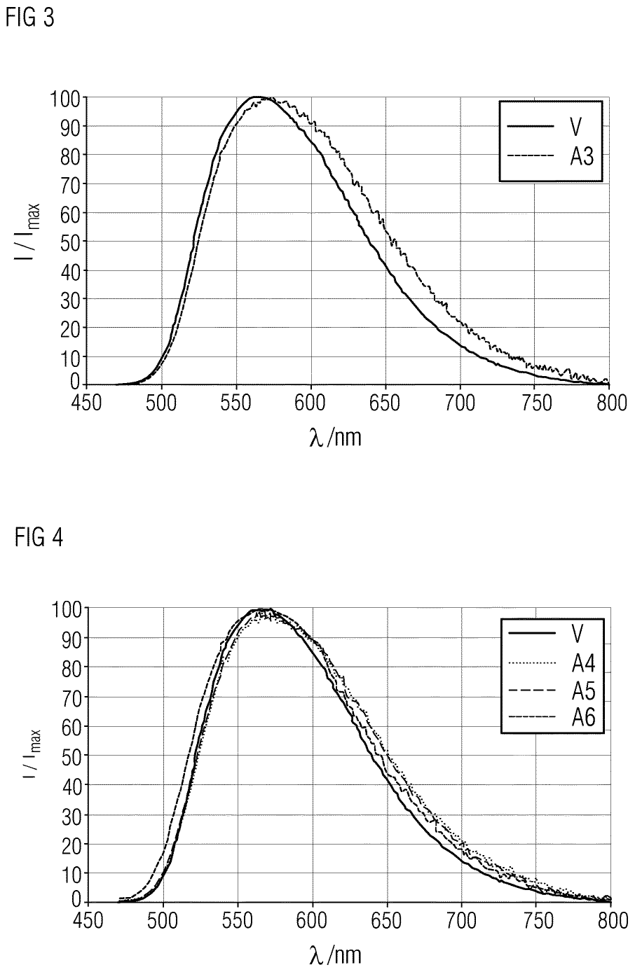

FIGS. 3 to 6 show emission spectra of exemplary embodiments and a comparative example.

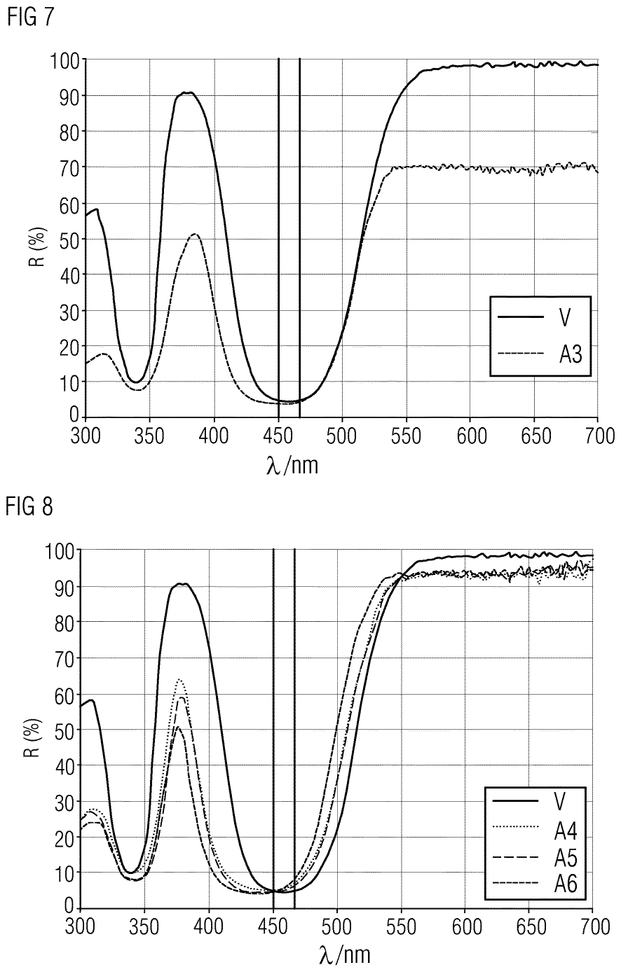

FIGS. 7 to 10 show reflection spectra of exemplary embodiments and a comparative example.

Elements that are identical, similar or have the same effect are marked with the same reference symbols in the figures.

The figures and the proportions of the elements shown in the figures are not to be regarded as true to scale. Rather, individual elements, in particular layer thicknesses, may be shown in exaggerated size for better visualization and/or understanding.

FIG. 1 shows a schematic sectional view of a radiation-emitting component 100 according to an embodiment example. The radiation-emitting component 100 has a semiconductor chip 10. During operation, the semiconductor chip 10 emits electromagnetic radiation of a first wavelength range (primary radiation) from a radiation exit surface 11. The semiconductor chip 10 has an epitaxially grown semiconductor layer sequence with an active zone that is suitable for generating electromagnetic radiation. The primary radiation has wavelengths in the blue and/or ultraviolet range, for example. In particular, the semiconductor chip 10 is an LED chip.

Furthermore, the component has a conversion element 20. The conversion element 20 either contains a matrix material in which the conversion substance 1, in particular particles of the conversion substance 1, is embedded, or the conversion element 20 has or consists of a ceramic formed from the conversion substance 1. Alternatively, the conversion element 20 contains a matrix material in which the mixture of substances 2, in particular particles of the mixture of substances 2, is embedded, or the conversion element 20 has a ceramic formed from the mixture of substances 2 or consists thereof.

The matrix material is selected from polymers such as polystyrene, polysiloxane, polysilazane, PMMA, polycarbonate, polyacrylate, polytetrafluoroethylene, polyvinyl, silicone resin, silicone, epoxy resin and transparent synthetic rubber, and glass such as silicates, water glass and quartz glass.

During operation, the conversion substance 1 and the substance mixture 2 partially convert electromagnetic radiation of the first wavelength range into electromagnetic radiation of the second wavelength range (secondary radiation). If the primary radiation is not completely converted by the conversion element, the component thus emits mixed light, which is composed of primary and secondary radiation. However, due to the conversion substance 1 alone or in the mixture of substances 2, part of the absorbed primary radiation is not converted into secondary radiation, but charge transport and radiation-free recombination occur.

The conversion element 20, which is designed here as a conversion layer, can either be applied directly to the semiconductor chip 10 or attached to it, for example by means of an adhesive layer (not explicitly shown here).

The semiconductor chip 10 with the conversion element 20 arranged thereon is arranged in the recess of a housing 30. The housing 30 has side surfaces which are beveled towards the semiconductor chip 10 and can be reflective. The semiconductor chip 10 and the conversion element 20 may be surrounded by a potting 40 in the housing 30, as shown here. However, the presence of a potting 40 is not absolutely necessary. The potting can be formed from a silicone or epoxy resin, for example, and has a transmittance for electromagnetic radiation of the active zone that is at least 85%, preferably 95%.

Alternatively, the housing 30 can also have no side walls and thus no recess and be designed as a carrier (not shown here).

FIG. 2 shows another exemplary embodiment of a radiation-emitting component. The explanations made with reference to FIG. 1 apply to the elements with the same reference signs. In this exemplary embodiment, the conversion element 20 is not arranged directly on the semiconductor chip 10, but spaced from it on the side of the potting 40 facing away from the semiconductor chip 10. Here too, the conversion element 20 is again formed as a conversion layer.

The components shown in FIGS. 1 and 2 are LEDs, for example. For the sake of clarity, additional elements, such as electrical contacts, are not shown in FIGS. 1 and 2.

In the following, the properties of the conversion substance 1 or the mixture of substances 2 and the process for the production of the conversion substance 1 are explained in more detail with reference to exemplary embodiments.

In the process for the production of the conversion substance 1, exemplary embodiments A3 to A12 are prepared on the basis of the general formula Gd₃₋ₓCeₓ(Sc_{5-y-z}Al_{y}Ga_{z})O₁₂ with different proportions of Sc, Al and Ga and of Gd and Ce. As reactants Gd₂O₃, CeO₂, Al₂O₃, Sc₂O₃ and Ga₂O₃ are homogeneously mixed with a formal excess of Al or Ga and heated with the addition of one or more fluxing agents. Heating takes place for 3 hours in a forming gas atmosphere at 1500° C. in an Al₂O₃ crucible with a lid. The resulting annealing cakes are crushed and ground using a mortar mill.

Table 1 shows the initial weights for the respective embodiments:

TABLE 1

| | Composition | Gd₂O₃ | CeO₂ | Al₂O₃ | | Sc₂O₃ | | Ga₂O₃ | | Excess |
|---|---|---|---|---|---|---|---|---|---|---|
| A3 | Gd_{2.7}Ce_{0.3}Sc₁Al₃Ga₁O₁₂ | 42.846 g | 4.521 g | 14.591 | g | 6.037 | g | 8.206 | g | Al |
| A4 | Gd_{2.7}Ce_{0.3}Sc₂Al₂Ga₁O₁₂ | 41.965 g | 4.428 g | 9.944 | g | 11.826 | g | 8.037 | g | Al |
| A5 | Gd_{2.7}Ce_{0.3}Sc₁Al₂Ga₂O₁₂ | 40.810 g | 4.306 g | 9.703 | g | 5.750 | g | 15.631 | g | Al |
| A6 | Gd_{2.7}Ce_{0.3}Sc₂Al₁Ga₂O₁₂ | 40.010 g | 4.222 g | 5.368 | g | 11.275 | g | 15.325 | g | Al |
| A7 | Gd_{2.7}Ce_{0.3}Sc₁Al₁Ga₃O₁₂ | 38.958 g | 4.111 g | 5.259 | g | 5.489 | g | 22.383 | g | Al |
| A8 | Gd_{2.7}Ce_{0.3}Sc₂Ga₃O₁₂ | 38.229 g | 4.034 g | 1.200 | g | 10.773 | g | 21.964 | g | Al |
| A9 | Gd_{2.7}Ce_{0.3}Sc₁Ga₄O₁₂ | 37.267 g | 3.932 g | 1.200 | g | 5.251 | g | 28.849 | g | Al |
| A10 | Gd_{2.7}Ce_{0.3}Sc₂Ga₃O₁₂ | 38.229 g | 4.034 g | 0.00 | g | 10.773 | g | 23.064 | g | Ga |
| A11 | Gd_{2.55}Ce_{0.45}Sc₂Ga₃O₁₂ | 36.157 g | 6.059 g | 0.00 | g | 10.789 | g | 23.096 | g | Ga |

| | | | | | | | | | |
|---|---|---|---|---|---|---|---|---|---|
| A12 | Gd_{2.4}Ce_{0.6}Sc₂Ga₃O₁₂ | 34.079 g | 8.090 g | 0 | g | 10.804 | g | 23.127 | Ga |

The powder samples are then analyzed using a powder diffractometer and Fluoromax. The powder diffractometer allows the purity of the samples to be examined and the lattice parameter a to be determined. The quantum efficiency QE, the dominant wavelength Adom of the residual emission and the remission R at the spectral ranges of interest can be obtained from the Fluoromax measurement.

To determine the dominant wavelength of the electromagnetic radiation emitted by the conversion substance, a straight line is drawn in the CIE standard diagram from the white point through the color location of the electromagnetic radiation. The intersection of the straight line with the spectral color line delimiting the CIE standard diagram denotes the dominant wavelength of the electromagnetic radiation. In general, the dominant wavelength deviates from the wavelength of the emission maximum.

Table 2 shows the spectral data and the lattice parameter a of the exemplary embodiments A3 to A12 and the comparative example V (YAG:Ce):

TABLE 2

| | QE | R_{min450-470 nm} | R_{min680-700 nm} | λ_{dom} | a |
|---|---|---|---|---|---|
| | [%] | [%] | [%] | [nm] | [Å] |
| A3 | 19 | 5 | 70 | 576 | 12.28 |
| A4 | 17 | 7 | 93 | 575 | 12.42 |
| A5 | 28 | 6 | 95 | 575 | 12.33 |
| A6 | 16 | 7 | 94 | 573 | 12.46 |
| A7 | 11 | 10 | 88 | 572 | 12.36 |
| A8 | 6 | 8 | 95 | 573 | 12.50 |
| A9 | 5 | 15 | 89 | 573 | 12.42 |
| A10 | 1.4 | 8 | 94 | 571 | 12.53 |
| A11 | 0.5 | 9 | 91 | 570 | 12.57 |
| A12 | 0.7 | 10 | 77 | 573 | 12.53 |
| V | 84 | 5 | 98 | 574 | 12.01 |

From the measured lattice parameters a, it can be seen that the crystal lattice expands as expected due to the insertion of the larger ions compared to the reference example V with a lattice parameter of 12.01 Å. This makes it possible to increase the content of the activator element Ce³⁺ in the conversion substance 1.

The spectral data show that the quantum efficiency QE is significantly reduced by the high Ce content. The aluminum-free samples (A8 to A12) show the lowest quantum efficiencies, especially the samples in which the excess Al was replaced by excess Ga (A10 to A12).

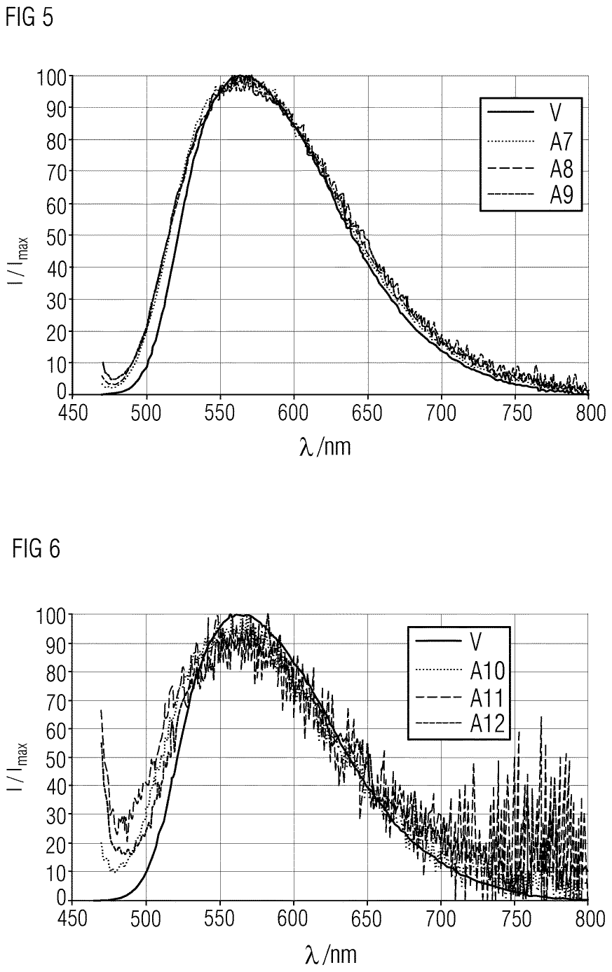

FIGS. 3 to 6 show the emission spectra of the exemplary embodiments A3 to A12 in comparison with the reference YAG:Ce. In each case, the wavelength λ in nm is plotted against the relative intensity I/Iₘₐₓ. FIG. 3 shows the spectrum of example A3, FIG. 4 shows the spectra of examples A4 to A6, FIG. 5 shows the spectra of examples A7 to A9, and FIG. 6 shows the spectra of examples A10 to A12. The spectra in FIGS. 3 to 6 are each shown together with the spectrum of the comparative example YAG:Ce (labeled V).

Based on all emission spectra of the exemplary embodiments in comparison to YAG:Ce, it can be seen that the exemplary embodiments have an emission maximum that hardly differs from the comparative example. This means that the conversion substances according to the exemplary embodiments can also be used well in a mixture of substances with the comparative example in order to generate a reduced brightness while maintaining the same color location. However, due to the existing emission of the exemplary embodiments, they can also be used without light-emitting substance in the conversion element 20 in order to provide a component with reduced brightness.

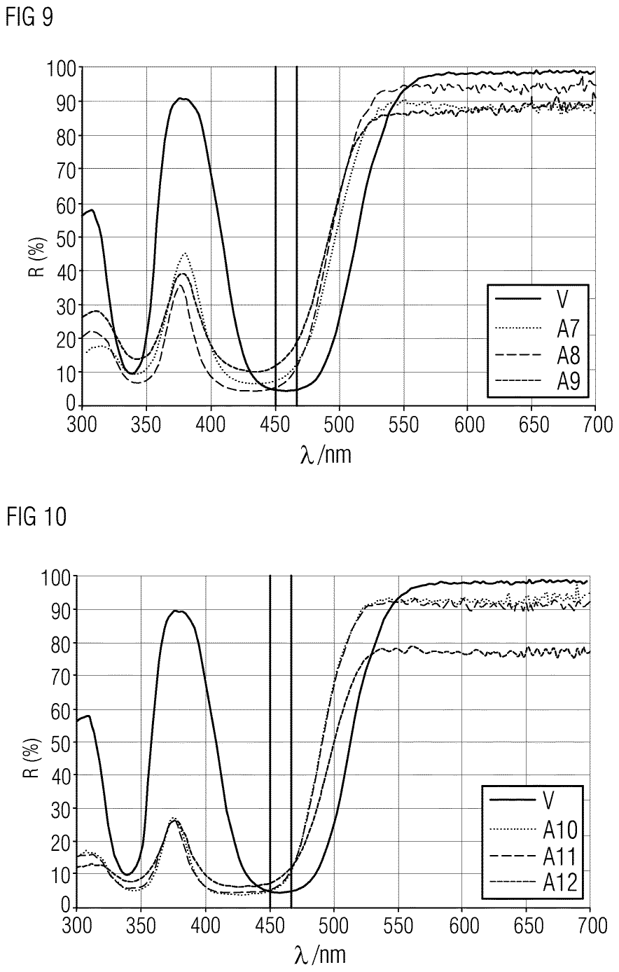

FIGS. 7 to 10 show reflection spectra of exemplary embodiment A3 (FIG. 7), exemplary embodiments A4 to A6 (FIG. 8), exemplary embodiments A7 to A9 (FIG. 9) and exemplary embodiments A10 to A12 (FIG. 10), in each case in comparison with the reference example YAG:Ce (labeled V). The wavelength λ in nm is plotted against the reflectance R in %. The emission range of the LED chip between 450 and 470 nm is marked in the spectra.

Overall, all samples in the emission range of the blue LED, i.e. at wavelengths from 450 to 470 nm, exhibit a low reflectance Rₘᵢₙ₄₅₀₋₄₇₀ₙₘ, which means that these samples strongly absorb the blue light. The observable small differences in Rₘᵢₙ₄₅₀₋₄₇₀ₙₘ between these samples can mainly be attributed to a different grain size distribution and grain morphology and thus a changed scattering behavior.

The different remissions Rₘᵢₙ₆₈₀₋₇₀₀ₙₘ in the wavelength range 680 nm to 700 nm indicate the degree of graying of the conversion substance. The differences between the samples produced can be attributed to different strong reactions between the conversion substance and the crucible material during heating. The contact area was relatively large in these exemplary embodiments, as the amount of sample produced in each case was small with 75 g. From the general experience of garnet synthesis, it is possible to avoid this problem when manufacturing in production size, so that graying is largely avoided.

The features and exemplary embodiments described in connection with the figures can be combined with one another according to further exemplary embodiments, even if not all combinations are explicitly described. Furthermore, the exemplary embodiments described in connection with the figures may alternatively or additionally have further features as described in the general part.

The invention is not limited to the description based on the exemplary embodiments. Rather, the invention includes any new feature as well as any combination of features, which includes in particular any combination of features in the patent claims, even if this feature or this combination itself is not explicitly stated in the patent claims or exemplary embodiments.

This patent application claims the priority of the German patent application 102022126560.9, the disclosure of which is hereby incorporated by reference.

### REFERENCES

1 Conversion substance
2 Mixture of substances
10 Semiconductor chip
11 Radiation exit surface
20 Conversion element
30 Housing
40 Potting
100 Radiation-emitting component
A3 Conversion substance according to exemplary embodiment
A4 Conversion substance according to exemplary embodiment
A5 Conversion substance according to exemplary embodiment
A6 Conversion substance according to exemplary embodiment
A7 Conversion substance according to exemplary embodiment
A8 Conversion substance according to exemplary embodiment
A9 Conversion substance according to exemplary embodiment
A10 Conversion substance according to exemplary embodiment
A11 Conversion substance according to exemplary embodiment
A12 Conversion substance according to exemplary embodiment
V Comparative example
R Reflection
λ Wavelength
I/Iₘₐₓ Relative intensity

1. A conversion substance of the general formula
RE¹₃₋ₓRE²ₓ(Sc_{5-y-z}Al_{y}Ga_{z})O₁₂, wherein
RE¹ is an element or a combination of elements selected from the group of rare earth elements,
RE² is an element or a combination of elements selected from the group of rare earth elements,
RE¹ and RE² are selected differently from each other, and it is 0.25<x<0.65, 0≤y≤5, 0<z≤5 and y+z≤5.

2. The conversion substance according to claim 1, wherein RE¹ is an element or a combination of elements selected from the group Gd, Y, La and Lu.

3. The conversion substance according to claim 1, wherein RE² is an element or a combination of elements selected from the group Ce and Eu.

4. The conversion substance according to claim 1, having the general formula Gd₃₋ₓCeₓ(Sc_{5-y-z}Al_{y}Ga_{z})O₁₂.

5. The conversion substance according to claim 1, wherein the conversion substance has an absorption range with an absorption maximum in the UV to blue spectral range.

6. The conversion substance according to claim 5, wherein the absorption maximum is in the range including 430 nm to including 490 nm.

7. The conversion substance according to claim 1, having a quantum efficiency selected from the range ≥0% to <100%.

8. The conversion substance according to claim 7, wherein the quantum efficiency is <20%.

9. The conversion substance according to claim 1, which crystallizes in a cubic space structure.

10. A mixture of substances comprising a conversion substance of the general formula
RE¹₃₋ₓRE²ₓ(Sc_{5-y-z}Al_{y}Ga_{z})O₁₂, wherein
RE¹ is an element or a combination of elements selected from the group of rare earth elements,
RE² is an element or a combination of elements selected from the group of rare earth elements,
RE¹ and RE² are selected differently from each other, and it is 025<x<0.65, 0≤y≤5, 0<z≤5 and y+z≤5,
and a light-emitting substance, the light-emitting substance having the general formula
RE¹₃₋ₖRE²ₖ(Al,Ga)₅O₁₂, wherein
RE¹ is an element or a combination of elements selected from the group of rare earth elements,
RE² is an element or a combination of elements selected from the group of rare earth elements,
RE¹ and RE² are selected differently from each other, and it is 0<k≤0.2.

11. The mixture of substances according to claim 10, wherein the conversion substance is present in the mixture of substances in a proportion selected from the range >0% and <100%.

12. The mixture of substances according to claim 11, wherein the light-emitting substance has an absorption range with an absorption maximum, wherein the absorption maximum has a position which is essentially identical to a position of the absorption maximum of the conversion substance.

13. The mixture of substances according to claim 11, wherein the light-emitting substance and the conversion substance have emission spectra which are substantially identical.

14. The mixture of substances according to claim 10, comprising the light-emitting substance YAG:Ce.

15. A process for the production of a conversion substance of the general formula RE¹₃₋ₓRE²ₓ(Sc_{5-y-z}Al_{y}Ga_{z})O₁₂, wherein
RE¹ is an element or a combination of elements selected from the group of rare earth elements,
RE² is an element or a combination of elements selected from the group of rare earth elements,
RE¹ and RE² are selected differently from each other, and it is 025<x<0.65, 0≤y≤5, 0<z≤5 and y+z≤5, comprising the steps of
providing a mixture of reactants selected from a group comprising oxides, nitrides, carbonates, nitrates, oxalates, citrates and hydroxides, each of RE¹, RE², Sc, Al and Ga, and combinations thereof,
homogeneous mixing of the reactants,
heating the reactants to a temperature selected from the range including 1200° C. to including 1900° C.

16. The process according to claim 15, wherein Al and/or Ga are present in excess in the mixture of reactants.

17. The process according to claim 15, wherein one or more fluxing agents are added to the mixture of reactants and/or wherein the heating is carried out under a forming gas atmosphere.

18. The process according to claim 15, wherein the heating is carried out for a period of from 1 h to 5 h.

19. A radiation emitting component with
a semiconductor chip which emits electromagnetic radiation of a first wavelength range during operation,
a conversion element comprising a conversion substance of the general formula
RE¹₃₋ₓRE²ₓ(Sc_{5-y-z}Al_{y}Ga_{z})O₁₂, wherein
RE¹ is an element or a combination of elements selected from the group of rare earth elements,
RE² is an element or a combination of elements selected from the group of rare earth elements,
RE¹ and RE² are selected differently from each other, and it is 0.25<x<0.65, 0≤y≤5, 0<z≤5 and y+z≤5 or comprises a mixture of substances according to claim 10, and which converts electromagnetic radiation of the first wavelength range into electromagnetic radiation of a second wavelength range which is partially different from the first wavelength range.

20. The radiation emitting component according to the claim 19, wherein the semiconductor chip is a light emitting diode chip.
